(19) United States
(12) Patent Application Publication
(10) Pub. No.: US 2004/0189336 A1
(43) Pub. Date: Sep. 30, 2004

(54) Apparatus for monitoring the connection state of connectors and a method for using the same

(75) Inventor: Steven T. Fink, Mesa, AZ (US)

Correspondence Address: PILLSBURY WINTHROP, LLP, P.O. BOX 10500, MCLEAN, VA, 22102, US

(73) Assignee: Tokyo Electron Limited, Tokyo (JP)

(21) Appl. No.: 10/807,383

(22) Filed: Mar. 24, 2004

Related U.S. Application Data
(60) Provisional application No. 60/457,328, filed on Mar. 26, 2003.

(51) Int. Cl. G01R 31/02

(52) U.S. Cl. 324/756

(57) ABSTRACT

An apparatus and method for determining the connection status between a first apparatus and a second apparatus configured to be electrically and mechanically coupled to the first apparatus. A probe is coupled to the first apparatus. The probe is electrically coupled to the second apparatus when the first apparatus and the second apparatus are coupled. When the first apparatus and the second apparatus are separated, the probe disengages the second apparatus to signal disconnection of the first apparatus and the second apparatus.

This application claims the benefit of U.S. Provisional Application No. 60/457,328, filed on Mar. 26, 2003, the contents of which are incorporated in their entirety herein by reference.

### BACKGROUND OF THE INVENTION

1. Field of the Invention

The present invention relates to an apparatus and method for determining the state of a connector.

2. Description of Related Art

Radio frequency (RF) connections can be used to provide RF energy between devices which are coupled through an interface. For example, in a plasma processing apparatus, an RF interface may exist between a plasma source and an impedance match network.

It may be desired to determine the connection status of the devices. For example, if the devices are separated without turning the RF energy source off first, serious injury or in some cases death may result from exposure to RF contacts which are energized.

Many other applications exist where it is desirable to determine the status of an electrical connector.

### SUMMARY OF THE INVENTION

The present invention provides a novel method and apparatus for determining the connection status of a connector.

The apparatus is provided with a first apparatus and a second apparatus configured to be electrically and mechanically coupled to the first apparatus. The apparatus further includes a mounting device located within the first apparatus and a probe configured to be mounted within the mounting device. The probe is electrically coupled to the second apparatus when the first apparatus and the second apparatus are coupled. When the first apparatus and the second apparatus are separated, the probe disengages the second apparatus to signal the status of the connector. The device may also include an insulator around the probe. In embodiments, the first apparatus may be an impedance match network and the second apparatus may be a plasma source housing or the first apparatus and the second apparatus may be cables.

The method uses a probe to monitor disconnection between a first apparatus and a second apparatus, where the probe is mounted on the first apparatus. The method includes coupling the probe electrically to the second apparatus when the first apparatus and the second apparatus are coupled, completing an electrical circuit between the first apparatus and the second apparatus through the probe when the first apparatus and the second apparatus are connected, and detecting when the probe disengages from the second apparatus to break the electrical circuit.

### BRIEF DESCRIPTION OF THE DRAWINGS

The accompanying drawings, which are incorporated in and constitute a part of the specification, of embodiments of the invention, together with the general description given above and the detailed description of the embodiments given below, serve to explain the principles of the invention wherein:

FIG. 1 is a cross-sectional view of an embodiment of a radio frequency (RF) joint between a plasma source and an impedance match network in accordance with the principles of the present invention;

FIG. 2 is an exploded view of the probe between a plasma source and an impedance match network shown by reference 2 in FIG. 1 in accordance with the principles of the present invention;

FIG. 3 is cross-sectional view of an embodiment of a probe contact assembly interface in accordance with the principles of the present invention;

FIG. 4 is a cross-sectional view of an embodiment of a probe contact assembly interface used in the mating of two cable assemblies in accordance with the principles of the present invention;

FIG. 5 is a cross-sectional view of another embodiment of a probe contact assembly interface used in the mating of two cable assemblies in accordance with the principles of the present invention;

FIG. 6 is a cross-sectional view of an embodiment of a probe contact assembly interface used in the mating of a cable assembly to an electrical box assembly in accordance with the principles of the present invention; and

FIG. 7 is a schematic diagram of an embodiment of a probe contact assembly in accordance with the principles of the present invention.

### DETAILED DESCRIPTION OF SEVERAL EMBODIMENTS OF THE INVENTION

The present invention will be described below with reference to the illustrative embodiments disclosed.

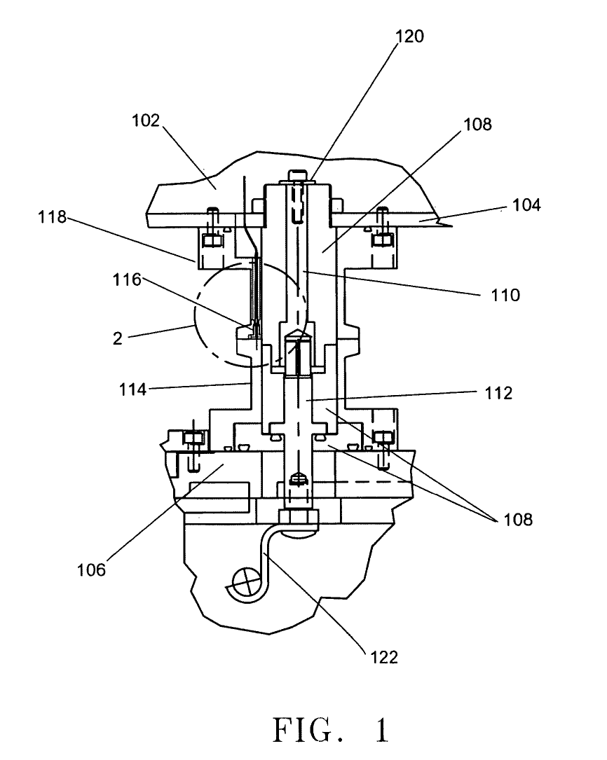

FIG. 1 is a cross-sectional view of an-embodiment of a radio frequency (RF) connection between a plasma source 106 and an impedance match network 102 in accordance with the principles of the present invention. As shown, the impedance match network 102 is coupled to the plasma source housing 106. The impedance match network 102 includes a match assembly housing 104 and an RF connection 120 for connection to impedance match network components. The RF connection 120 is coupled to a center conductor 110 which may be coupled to a center conductor 112 of the plasma source housing 106 which is in turn coupled to an RF tap 122 of the plasma source. An insulator 108 may surround the center conductors 110 and 112. The insulator 108 can prevent access to the center conductors 110 and 112 when the plasma source 106 and impedance match network 102 are coupled. The impedance match network 102 also includes a RF connector housing 118 to house a pin assembly 116. The plasma source housing 106 includes an RF connector housing 114 to contact with the pin assembly 116. The RF connector housing 114, in embodiments, includes at least a portion which contacts pin assembly 116 and is conductive and grounded.

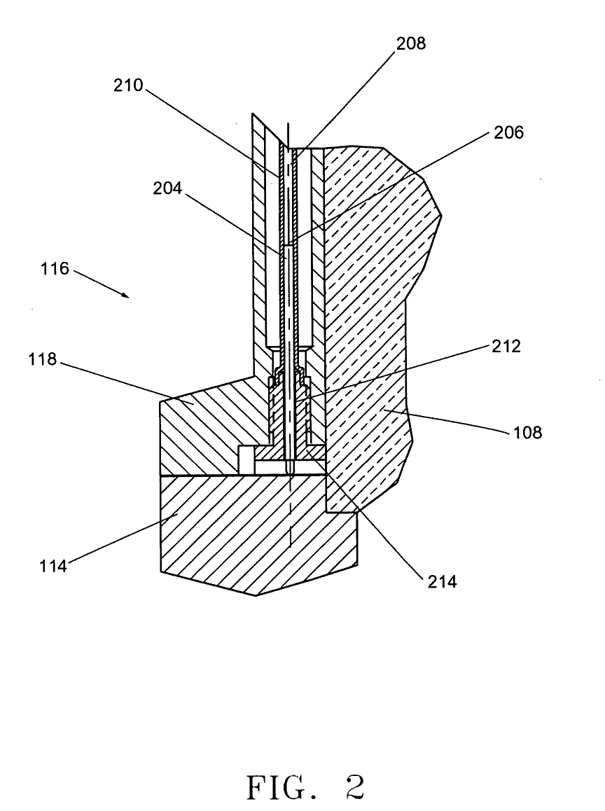

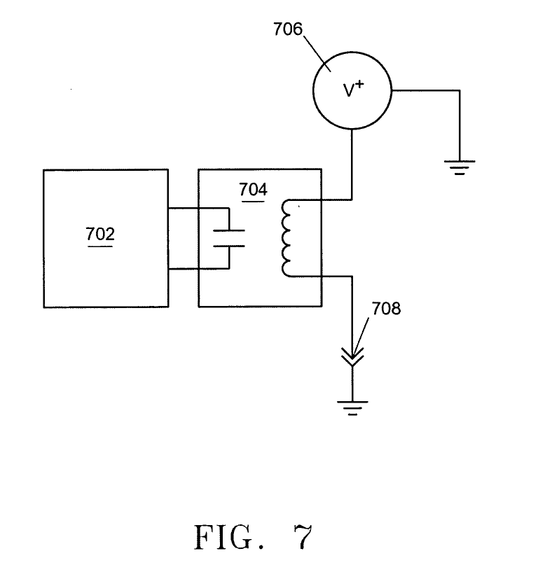

FIG. 2 is an exploded view of the probe between a plasma source housing 106 and an impedance match network 102 shown by reference 2 in FIG. 1 in accordance with the principles of the present invention. More specifically, FIG. 2 illustrates a more detailed embodiment of the pin assembly 116 shown in FIG. 1. The pin assembly includes a connection wire 208 which is coupled to a spring contact probe 204 by any of numerous methods including a solder joint 206. The entire assembly is then surrounded by an insulator 210. The ground pin assembly 116 may also include a mount 214 which is configured to engage the spring contact probe 204 at a bond surface 212. The spring contact probe 204 is in contact with the RF connector housing 114 when the plasma source 106 and the impedance match network 102 are coupled. As mentioned above, in embodiments, at least a portion of the RF connector housing which contacts probe 204 is conductive and grounded. Once the plasma source 106 and the impedance match network 102 are decoupled, the spring contact probe 204 will be disconnected from RF connector housing 114 which will cause the RF energy to be de-energized, the details of which are provided with reference to the schematic in FIG. 7.

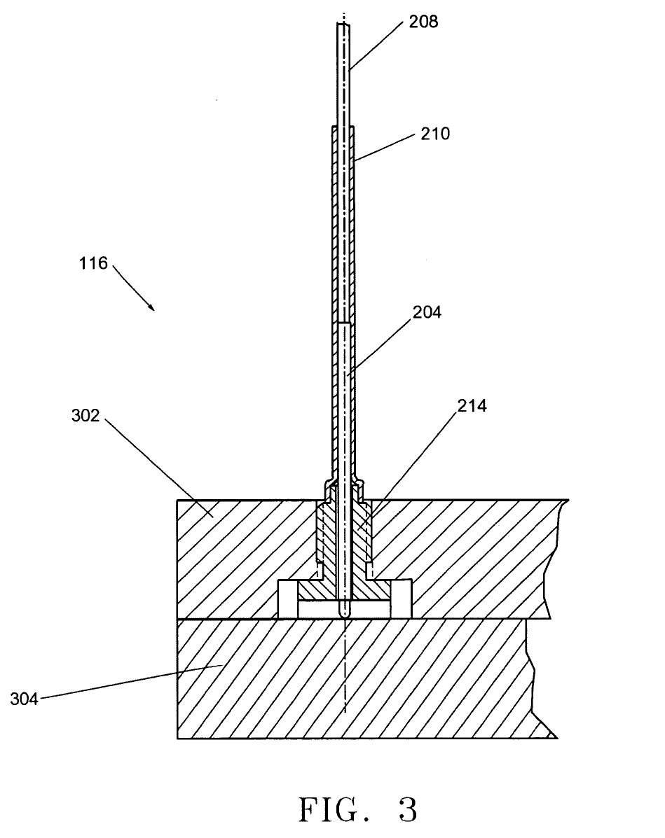

FIG. 3 is cross-sectional view of an embodiment of a probe contact assembly interface in accordance with the principles of the present invention. Although FIG. 2 describes the ground pin assembly 116 integrated between the plasma source 106 and the impedance match network 102, FIG. 3 is provided as an exemplary embodiment of a more generic system. As shown mounting plate 302 is coupled to conductive stop plate 304. Accordingly, the spring contact probe 204 electrically and mechanically engages the stop plate when the mounting plate 302 and conductive stop plate 304 are coupled. Once separated, the spring contact probe 204 is electrically disconnected from the conductive stop plate 304 opening a circuit formed to include probe 204 and conductive stop plate 304. The opening of the circuit signals that the mounting plate 302 and stop plate 304 have separated.

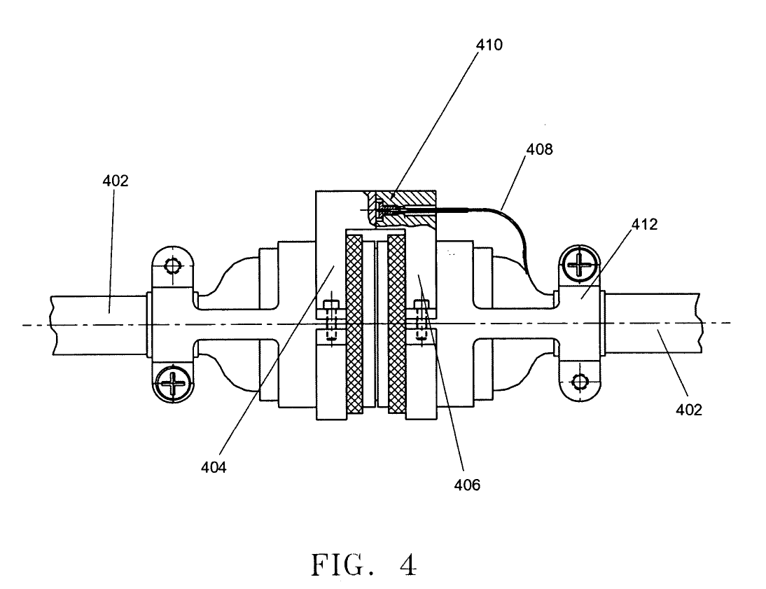

FIG. 4 is a cross-sectional view of an embodiment of a probe contact assembly interface used in the mating of two cable assemblies in accordance with the principles of the present invention. As shown, cable assemblies 402 are coupled together at an interface. The cable assemblies may include a strain relief mechanism 412 which is configured to reduce the stress of the connection between the two cables 402. One of the two cables includes probe contact lead wire 408 which extends into a probe contact assembly 410. The probe contact assembly may be similar to the assemblies described above. Additionally, a probe contact assembly housing 406 may be provided to house the probe contact assembly 410. The other cable may include a ground backing block assembly 404 which engages one end of the probe contact assembly. Again, as would be understood by a person skilled in the art, as the cables are separated, the ground connection between the probe and ground backing block assembly 404 is disconnected, signaling that the cables have decoupled and, perhaps, should be de-energized.

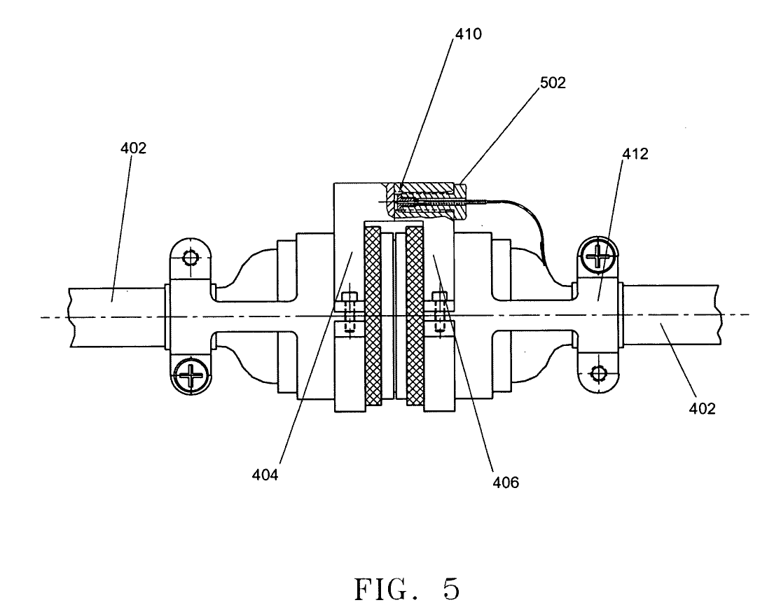

FIG. 5 is a cross-sectional view of another embodiment of a probe contact assembly interface used in the mating of two cable assemblies in accordance with the principles of the present invention. The embodiment shown in FIG. 5 is similar that shown in FIG. 4 except a probe adapter 502 is provided for probe contact assembly 410. In this manner, it may be possible to more easily fit the probe contact assembly into a plurality of devices since the adapter may be less expensive to manufacture and can be fitted to several different devices with a single design.

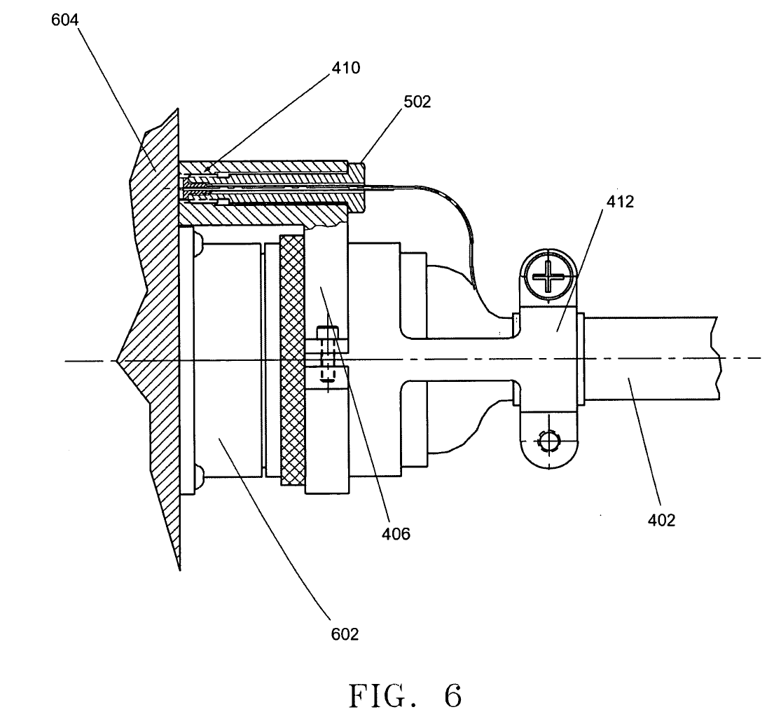

FIG. 6 is a cross-sectional view of an embodiment of a probe contact assembly interface used in the mating of a cable assembly to an electrical box assembly in accordance with the principles of the present invention. As shown, an electrical box assembly 604 is provided with a panel mounted connector 602. In this manner, it may be possible to couple the cable described above to the electrical box assembly, which in embodiments, may be grounded via a portion of the case. Again, as would be understood by a person skilled in the art, as the cable is separated from the electrical box assembly 604, the probe breaks contact with box assembly 604 and the opening of a circuit including these components signals disconnection of connector 602.

FIG. 7 is a schematic diagram of an embodiment of a probe contact assembly circuit in accordance with the principles of the present invention that can be employed with any of the embodiments described above. As shown, an RF generator 702 is coupled to a relay 704. The relay 704 is coupled to a voltage source 706. Also coupled to the relay 704 is the probe contact assembly 708. When the probe contact assembly 708 is separated, the ground connection is opened and the coil inside of relay 704 is in turn de-energized. The de-energization of the coil causes the RF generator 702 to become de-energized. Accordingly, the RF energy to a connector, for example, is turned off once the probe contact assembly is opened. As would be understood by a person skilled in the art, this embodiment of the circuitry is exemplary. Although the embodiments above have been described as opening a ground connection, it should be understood by a person skilled in the art that the probe does not have to be connected to ground. The probe can be connected to any part of the circuit and still function in a similar manner, i.e., once disconnected, the probe will open the circuit, signaling disconnection. Other embodiments utilize digital logic or integrated circuits to control the RF generator. Additionally, the circuit may be controlled by a computer which runs a monitoring program.

The foregoing presentation of the described embodiments is provided to enable any person skilled in the art to utilize the present invention. Various modifications to these embodiments are possible and the generic principle of a method and apparatus for safely separating an RF connector presented herein may be applied to other embodiments as well. For example, the present invention could be used to monitor the connection status of any connection. Thus, the present invention is not intended to be limited to the embodiments shown above, but rather to be accorded the widest scope consistent with the principles and novelty of the features disclosed in any fashion herein.

What is claimed is:

1. An apparatus for monitoring the connection status of a connector, said apparatus comprising:
a first apparatus;
a second apparatus configured to be electrically and mechanically coupled to said first apparatus;
a mounting device located within said first apparatus; and
a probe configured to be mounted within said mounting device;
wherein said probe is electrically coupled to said second apparatus when said first apparatus and said second apparatus are coupled and when said first apparatus and said second apparatus are separated, said probe disengages from said second apparatus to signal disconnection between said first apparatus and said second apparatus.

2. The apparatus as claimed in claim 1, further comprising a controller coupled to said probe, said controller being configured to provide power to said first apparatus and said second apparatus and disconnect power between said first apparatus and said second apparatus when said probe disengages from said second apparatus to signal disconnection between said first apparatus and said second apparatus.

3. The apparatus as claimed in claim 1, further comprising an insulator around said probe.

4. The apparatus as claimed in claim 1, wherein said first apparatus is an impedance match network and said second apparatus is a plasma source housing.

5. The apparatus as claimed in claim 1, wherein said first apparatus and said second apparatus are cables.

6. The apparatus as claimed in claim 1, further comprising a probe adapter configured to couple said probe to said mounting device.

7. The apparatus as claimed in claim 1, wherein said probe further includes a spring which is configured to force said probe to contact said second apparatus when said first apparatus and said second apparatus are coupled.

8. A method for safely separating radio-frequency connectors which supply radio-frequency energy between said connectors, said method comprising:
mounting a probe on a first apparatus, said first apparatus being electrically and mechanically couplable to a second apparatus;
coupling said probe electrically to a controller at one end and to said second apparatus at another end when said first apparatus and said second apparatus are coupled; and
completing an electrical circuit between said first apparatus and said second apparatus through said probe when said first apparatus and said second apparatus are connected;
wherein when said first apparatus and said second apparatus are separated, said probe disengages from said second apparatus to break said electrical circuit and cause the supply of radio-frequency energy to be de-energized.

9. The method as claimed in claim 7, wherein said first apparatus is an impedance match network and said second apparatus is a plasma source housing.

10. The method as claimed in claim 7, wherein said first apparatus and said second apparatus are cables.

11. The method as claimed in claim 7, further comprising configuring a probe adapter to couple said probe to said mounting device.

12. The apparatus as claimed in claim 7, further comprising:
attaching a spring to said probe, said spring being configured to force said probe to contact said second apparatus when said first apparatus and said second apparatus are coupled.

13. A method for signaling disconnection between a first apparatus and a second apparatus, said method comprising:
mounting a probe on said first apparatus, said first apparatus being electrically and mechanically couplable to said second apparatus;
coupling said probe electrically to said second apparatus when said first apparatus and said second apparatus are coupled;
completing an electrical circuit between said first apparatus and said second apparatus through said probe when said first apparatus and said second apparatus are connected; and
detecting when said electrical circuit is broken to signal disconnection of said first apparatus from said second apparatus.

14. The method as claimed in claim 13, further comprising causing a supply of energy between said first apparatus and said second apparatus to be de-energized upon detecting that said electrical circuit is broken.

15. A method for using a probe to monitor disconnection between a first apparatus and a second apparatus, said probe being mounted on said first apparatus, said method comprising:
coupling said probe electrically to said second apparatus when said first apparatus and said second apparatus are coupled;
completing an electrical circuit between said first apparatus and said second apparatus through said probe when said first apparatus and said second apparatus are connected; and
detecting when said probe disengages from said second apparatus to break said electrical circuit.

16. The method as claimed in claim 15, further comprising causing a supply of energy between said first apparatus and said second apparatus to be de-energized upon detecting that said electrical circuit is broken.
